(19) United States
(12) Patent Application Publication
(10) Pub. No.: US 2015/0287632 A1
(43) Pub. Date: Oct. 8, 2015

(54) METHODS OF FABRICATING SEMICONDUCTOR DEVICE AND STACKED CHIP

(71) Applicant: OmniVision Technologies (Shanghai) Co., Ltd., Shanghai (CN)

(72) Inventors: Xifeng Gao, Shanghai (CN); Jing Ye, Shanghai (CN)

(73) Assignee: OmniVision Technologies (Shanghai) Co., Ltd., Shanghai (CN)

(21) Appl. No.: 14/266,750

(22) Filed: Apr. 30, 2014

(30) Foreign Application Priority Data
Apr. 4, 2014 (CN) 201410136618.0

(51) Int. Cl. H01L 21/768; H01L 25/00

(52) U.S. Cl. CPC H01L 21/76831; H01L 21/76802; H01L 25/50; H01L 2225/06541

(57) ABSTRACT

A method of fabricating a semiconductor device is disclosed. The method includes the steps of: providing a substrate having a device function layer formed thereon; forming a first opening in the device function layer, the first opening extending through the device function layer and having a side-to-bottom angle of smaller than 90°; and etching the substrate to form therein a second opening by using the device function layer as a mask and the first opening as a mask pattern. A method of fabricating a stacked chip is also disclosed, in which a second opening is formed in the same manner as the fabrication method of the semiconductor device. The fabrication methods are capable of simplifying semiconductor fabrication processes, increasing the throughput of a semiconductor fabrication plant and reducing fabrication cost.

### CROSS-REFERENCES TO RELATED APPLICATIONS

This application claims the priority of Chinese patent application number 201410136618.0, filed on Apr. 4, 2014, the entire contents of which are incorporated herein by reference.

### TECHNICAL FIELD

The present invention relates generally to semiconductor device fabrication, and in particular, to a method of fabricating a semiconductor device and a method of fabricating a stacked chip.

### BACKGROUND

With the development of multimedia technology, digital still cameras, digital video cameras and mobile phones with camera functions have gained increasing popularity among consumers. In addition to their pursuit for the miniaturization of these devices, customers are also demanding for an increasing improvement in the quality (i.e., clarity) of images captured by such devices. On the other hand, whether such a device could capture a high imaging quality heavily depends on what components the device incorporates. In particular, the imaging quality of a camera is determined by an incorporated imaging sensor, which is a critical component of the camera.

Nowadays, complementary metal-oxide-semiconductor (CMOS) image sensors adopting a stacked structure, thus referred to as stacked CMOS image sensors, are getting a greater share in the camera sensor market. Each of such stacked sensors is accomplished by a device chip (with pixels) and a logic chip (with circuitry) that is stacked and electrically interconnected with the device chip. Such architecture enables the stacked sensor to provide a great number of pixels while keeping a relatively small size. Additionally, dispersing the pixel and circuitry parts on different chips allows the parts to be optimized separately for a higher imaging quality and a higher performance, respectively. As a result, compared to conventional backside-illuminated (BSI) sensors, stacked sensors are typically smaller in size while having higher performance.

However, a problem associated with the stacked sensors is that the existing processes for their fabrication are generally complex (e.g., the formation of mask patterns involves the use of many masks), costly and low in throughput.

### SUMMARY OF THE INVENTION

It is therefore an objective of the present invention to provide a method of fabricating a semiconductor device and a method of fabricating a stacked chip, both capable of simplifying semiconductor fabrication processes (e.g., the fabrication processes of stacked sensors), increasing the throughput of a semiconductor fabrication plant (FAB) and reducing fabrication cost.

In accordance with the above and further objectives of the invention, a method of fabricating a semiconductor device includes: providing a substrate having a device function layer formed thereon; forming a first opening in the device function layer, the first opening extending through the device function layer, the first opening having a side-to-bottom angle of smaller than 90°; and etching the substrate to form therein a second opening by using the device function layer as a mask and the first opening as a mask pattern.

Optionally, the method may further include forming a first barrier layer on the device function layer, prior to forming the first opening in the device function layer.

Further, the first barrier layer may be formed of an oxide, a nitride or a carbide.

Further, the first barrier layer may have a thickness of 10 Å to 1000 Å.

Optionally, the method may further include forming a second barrier layer on the device function layer, after forming the first opening and prior to forming the second opening.

Further, the second barrier layer may be formed of an oxide, a nitride or a carbide.

Further, the second barrier layer may have a thickness of 10 Å to 5000 Å.

Further, the second barrier layer may have a non-conformal step coverage region in the first opening.

In another aspect, the present invention provides a method of fabricating a stacked chip, including: providing a first chip and a second chip, the first chip including a first substrate and a first epitaxial layer formed on the first substrate, the first epitaxial layer including a first interconnect structure, the second chip including a second substrate and a second epitaxial layer formed on the second substrate; stacking the first and second chips, with a side of the first epitaxial layer opposite the first substrate brought in contact with a side of the second epitaxial layer opposite the second substrate; forming a first opening in the first substrate, the first opening extending through the first substrate, the first opening having a side-to-bottom angle of smaller than 90°; and etching the first epitaxial layer to form therein a second opening by using the first substrate as a mask and the first opening as a mask pattern, the second opening exposing the first interconnect structure.

Further, the first interconnect structure may include a first cap metal layer and at least one metal interconnect layer, the first cap metal layer stacked with the at least one metal interconnect layer. Additionally, the first cap metal layer may be located on a side of the at least one metal interconnect layer opposite the first substrate, and the second opening may expose one of the at least one metal interconnect layer closest to the first substrate.

Further, the second epitaxial layer may include a second interconnect structure, and the method may further include forming, within the first opening, a third opening exposing the second interconnect structure.

Further, the third opening may be within the second opening.

Further, the second and third openings may be formed by an all-in-one etching process.

Further, the first epitaxial layer may include an interconnect region and an opening region. In addition, the first interconnect structure may be disposed in the interconnect region, and the third opening may be disposed in the opening region.

Further, the second interconnect structure may include a second cap metal layer, and the third opening may expose the second cap metal layer.

Optionally, the method may further include filling the first and second openings with a conductive layer.

Optionally, the method may further include forming a first barrier layer on a side of the first substrate opposite the first epitaxial layer, prior to forming the first opening.

Further, the first barrier layer may be formed of an oxide, a nitride or a carbide.

Further, the first barrier layer may have a thickness of 10 Å to 1000 Å.

Optionally, the method may further include forming a second barrier layer on the side of the first substrate opposite the first epitaxial layer, after forming the first opening in the first substrate and prior to forming the second opening in the first epitaxial layer.

Further, the second barrier layer may be formed of an oxide, a nitride or a carbide.

Further, the second barrier layer may have a thickness of 10 Å to 5000 Å.

Further, the second barrier layer may have a non-conformal step coverage region in the first opening.

The methods of the present invention provide the following advantages over the prior art.

First, in the fabrication of the semiconductor device according to the present invention, with the first opening having a side-to-bottom angle of smaller than 90° (i.e., broader at the bottom and narrower at the top) serving as a mask pattern for the subsequent etching step of forming the second opening in the substrate, the formed second opening gains a size equal to the top-edge size of the first opening. This circumvents the necessity of preparing a separate mask for forming the second opening, thus resulting in process simplification, enhanced productivity and cost reduction.

Secondly, by forming the first and second openings of a stacked chip in the same manner as the above-mentioned fabrication method of the semiconductor device, the forming method of the present invention can achieve all the same benefits, i.e., a simplified process, enhanced productivity and reduced cost.

### BRIEF DESCRIPTION OF THE DRAWINGS

FIG. 1 depicts a flowchart graphically illustrating a method of fabricating a semiconductor device in accordance with a first embodiment of the present invention.

FIGS. 2 to 5 show individual steps of the method of FIG. 1.

FIG. 6 is a flowchart illustrating a method of fabricating a stacked chip in accordance with a second embodiment of the present invention.

FIGS. 7 to 13 show individual steps of the method of FIG. 6.

### DETAILED DESCRIPTION

The methods of the present invention will be described in greater detail in the following description which demonstrates preferred embodiments of the present invention, in conjunction with the accompanying drawings. Those of skill in the art should, in light of the present disclosure, appreciate that many changes can be made in the specific embodiments disclosed herein and still obtain the same beneficial results. Therefore, the following description should be construed as the illustrative of the principles of the present invention, and not providing limitations thereto.

For simplicity and clarity of illustration, not all features of the specific embodiments are described. Additionally, descriptions and details of well-known functions and structures are omitted to avoid unnecessarily obscuring the invention. The development of any specific embodiment of the present invention includes specific decisions made to achieve the developer's specific goals, such as compliance with system-related and business-related constraints, which will vary from one implementation to another. Moreover, such a development effort might be complex and time consuming but would nevertheless be a routine undertaking for those of ordinary skill in the art.

The present invention will be further described in the following paragraphs by way of example with reference to the accompanying drawings. Features and advantages of the present invention will be apparent from the following detailed description, and from the appended claims. Note that the accompanying drawings are provided in a very simplified form not necessarily presented to scale, with the only intention of facilitating convenience and clarity in explaining a few exemplary embodiments of the present invention.

In accordance with the principles of the present invention, a method of fabricating a semiconductor device is provided, including the steps of:

step S11: providing a substrate having a device function layer formed thereon;

step S12: forming a first opening in the device function layer, the first opening extending through the device function layer, the first opening having a side-to-bottom angle of smaller than 90°; and

step S13: etching the substrate to form therein a second opening by using the device function layer as a mask and the first opening as a mask pattern.

Advantageously, with the first opening having a side-to-bottom angle of smaller than 90° (i.e., broader at the bottom and narrower at the top) serving as a mask pattern for the subsequent etching step for forming the second opening in the substrate, the formed second opening gains a size that is equal to the top-edge size of the first opening. This circumvents the necessity of preparing a separate mask for forming the second opening, thus resulting in process simplification, enhanced productivity and cost reduction.

In accordance with the principles of the present invention, a method of fabricating a stacked chip is also provided. In this method, a first opening and a second opening are formed in the same manner as the above-described fabricating method, and all the same benefits, i.e., a simplified process, enhanced productivity and reduced cost, are thus achievable. The fabricating method includes the steps of:

step S21: providing a first chip and a second chip, the first chip including a first substrate and a first epitaxial layer formed on the first substrate, the first epitaxial layer including a first interconnect structure, the second chip including a second substrate and a second epitaxial layer formed on the second substrate, the first chip and the second chip being stacked together with a side of the first epitaxial layer opposite the first substrate brought in contact with a side of the second epitaxial layer opposite the second substrate;

step S22: forming a first opening in the first substrate, the first opening extending through the first substrate, the first opening having a side-to-bottom angle of smaller than 90°; and

step S23: etching the first epitaxial layer to form therein a second opening that exposes the first interconnect structure by using the first substrate as a mask and the first opening as a mask pattern.

The present invention will become more apparent from the detailed description of several exemplary embodiments set forth below. It is to be understood that this invention is not limited to these embodiments, and modifications made thereto by those of ordinary skill in the art based on common technical means are also considered to be within the scope of the invention.

### EMBODIMENT 1

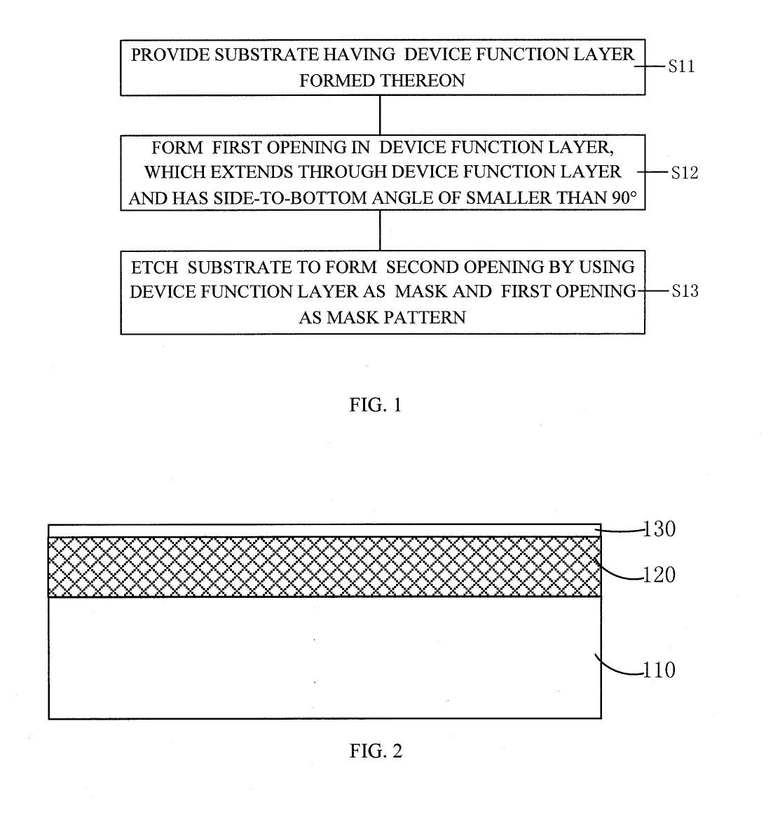

A method of fabricating a semiconductor device in accordance with this embodiment is described by referencing FIGS. 1-5, in which: FIG. 1 is a flowchart showing the sequential steps of the method collectively; while FIGS. 2-5 are schematic diagrams showing the same steps individually.

Turning now to FIG. 2, in the step S11 of the method, a substrate 110 having a device function layer 120 formed thereon is provided. While the substrate 110 and the device function layer 120 are illustrated in FIG. 2 as being formed of different materials, the present invention is not limited in this regard as the substrate 110 and the device function layer 120 may also be formed of the same material, or be different portions of the same layer.

Preferably, as shown in FIG. 2, a first barrier layer 130 is formed on a side of the device function layer 120 opposite the substrate 110 before proceeding to a subsequent step S12, for protecting the device function layer 120 from being affected in another subsequent step S13. Materials from which the first barrier layer 130 can be fabricated to ensure an effective protection for the device function layer 120 include oxides such as silicon dioxide, nitrides such as silicon nitride, and carbides such as silicon carbonitride. Preferably, first barrier layer 130 has a thickness of 10 Å to 1000 Å, for example, 50 Å, 100 Å, 300 Å, 500 Å, or 800 Å.

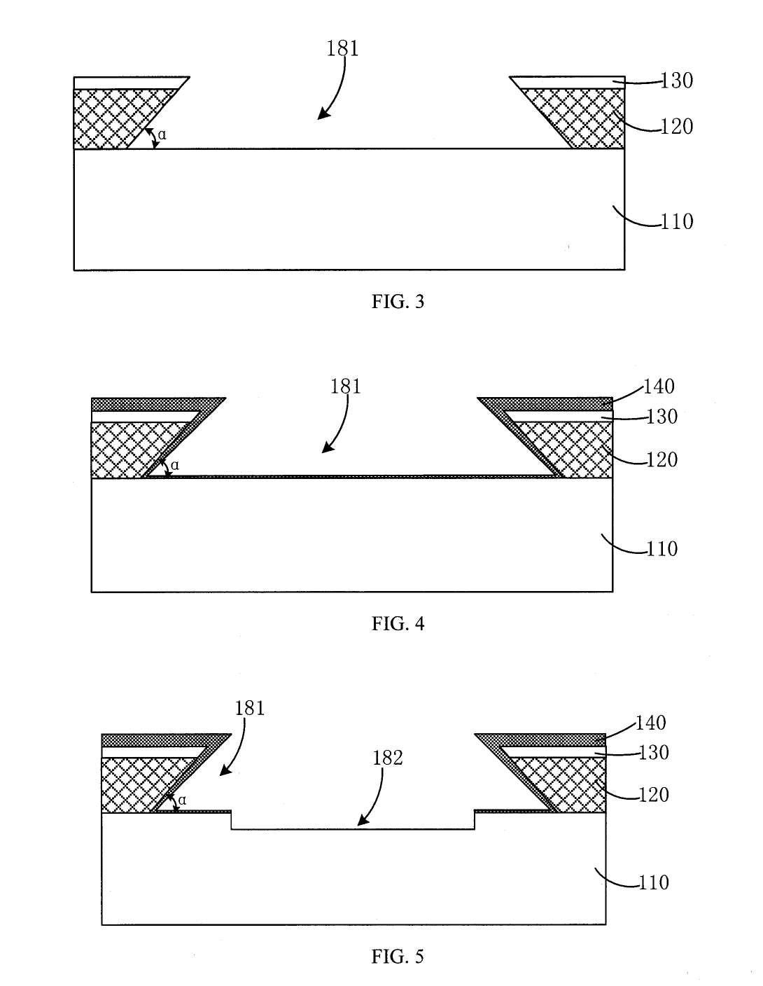

Referring to FIG. 3, in the step S12 of the method, a first opening 181 is formed in the device function layer 120. The first opening 181 extends through the device function layer 120 and its inner side is inclined with respect to the bottom at an angle (i.e., a side-to-bottom angle) a of smaller than 90°. In other words, the first opening 181 is broader at the bottom and narrower at the top. Speaking in still another way, the first opening 181 has a cross section resembling a regular trapezoid in shape. The angle α may be set to various values in accordance with practical needs, such as, for example, 80°, 60°, 45° or 30°. A dry etching process may be employed to form the first opening 181, and a suitable recipe may be selected for the etching process according to the material of the device function layer 120. As the selection of a suitable etching recipe for a certain material is well-known to those of ordinary skill in the art, further description of it is omitted for the sake of brevity.

In this embodiment, a second barrier layer 140 is further formed over the device function layer 120 before the next step S13 and after step S12. In this process, as shown in FIG. 4, the second barrier layer 140 covers an upper surface of the first barrier layer 130 or covers an upper surface of the device function layer 120 when the first barrier layer 130 is omitted. The second barrier layer 140 also covers both the inner side and the bottom of the first opening 181. For this reason, the second barrier layer 140 provides a protection for the device function layer 120 during the proceeding of the subsequent step S13. Similarly, materials from which the second barrier layer 140 can be fabricated to ensure an effective protection for the device function layer 120 include oxides such as silicon dioxide, nitrides such as silicon nitride, and carbides such as silicon carbonitride. Preferably, the second barrier layer 140 has a thickness of 10 Å to 5000 Å, for example, 50 Å, 100 Å, 300 Å, 1000 Å, or 3000 Å. Preferably, the second barrier layer 140 has a non-conformal step coverage, i.e., has inconsistent thicknesses inside and outside the first opening 181. In particular, a thickness of the portion covering the outside of the first opening 181 (i.e., the upper surface of the device function layer 120 or the first barrier layer 130) is greater than a thickness of the portion over the inside of the first opening 181 (i.e., the inner side and bottom of the first opening 181). In order for the non-conformal step coverage to occur, a chemical vapor deposition (CVD) process or other suitable process can be selected to form second barrier layer 140.

In the step S13, as shown in FIG. 5, the substrate 110 is etched to form therein a second opening 182 using the device function layer 120 as a mask and the first opening 181 as a mask pattern. The formed second opening 182 has a size that is equal to a top-edge size of the first opening 181. Advantageously, using the first opening 181 as a mask pattern in forming second opening 182 can eliminate the need for preparing a separate mask for the second opening 182, thus leading to process simplification, enhanced productivity and cost reduction.

### EMBODIMENT 2

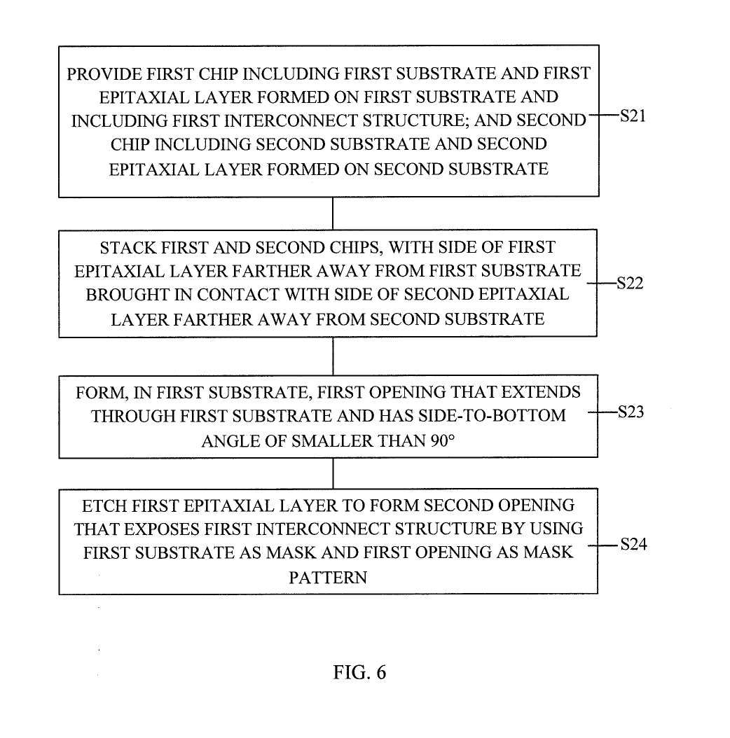

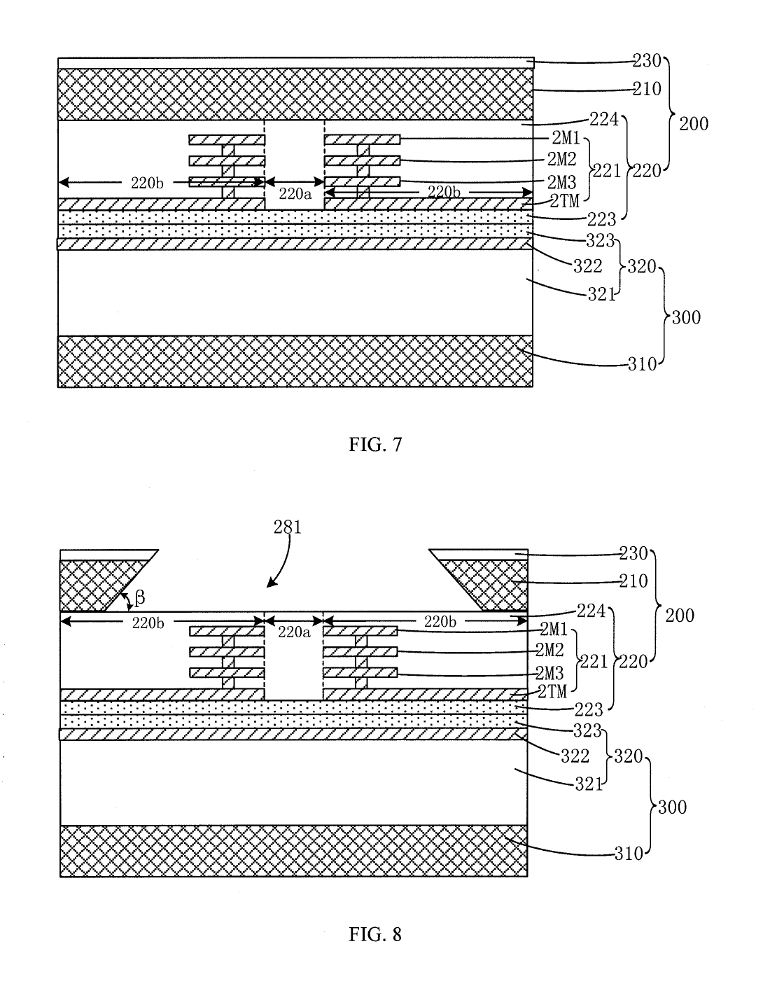

A method of fabricating a stacked chip in accordance with this embodiment is described by referencing FIGS. 6-13, in which: FIG. 6 is a flowchart showing the sequential steps of the method collectively; while FIGS. 7-13 are schematic diagrams showing the same steps individually. In this method, a second opening is formed in the same manner as the method of Embodiment 1.

Reference is first made to FIG. 7 which shows a first step S21 of the method of this embodiment, wherein a first chip 200 and a second chip 300 are provided. First chip 200 includes a first substrate 210 and a first epitaxial layer 220 formed on one side of first substrate 210. The first substrate 210 includes a first interconnect structure 221. The second chip 300 includes a second substrate 310 and a second epitaxial layer 320 formed on one side of the second substrate 310.

With continuing reference to FIG. 7, in a second step S22 of the method, the first and second chips 200, 300 are stacked up together, with a side of the first epitaxial layer 220 opposite the first substrate 210 being brought in contact with a side of the second epitaxial layer 320 opposite the second substrate 310.

The first epitaxial layer 220 may further include a first protective layer 223, a first dielectric layer 224 and other like features. The first protective layer 223 may be formed on a side of a first cap metal layer 2TM opposite the first substrate 210 so as to act as a protection layer of the first cap metal layer 2TM. First interconnect structure 221 may be disposed within the first dielectric layer 224 so as to be electrically insulated. As illustrated, the first epitaxial layer 220 has an interconnect region 220b and an opening region 220a, and the first interconnect structure 221 is formed in the interconnect region 220b.

In this embodiment, the first interconnect structure 221 includes a first metal interconnect layer 2M1, a second metal interconnect layer 2M2, a third metal interconnect layer 2M3 and aforementioned first cap metal layer 2TM. The first, second and third metal interconnect layers 2M1, 2M2 and 2M3 and the first cap metal layer 2TM are stacked together in this order, with the first cap metal layer 2TM disposed on a side of the third metal interconnect layer 2M3 opposite the first substrate 210. In alternative embodiments, the first interconnect structure 221 may only include the third metal interconnect layer 2M3 and the first cap metal layer 2TM, or only include the first cap metal layer 2TM, and both are considered within the scope of the invention. Further, while three metal interconnect layers (i.e., the first metal interconnect layer 2M1, the second metal interconnect layer 2M2 and the third metal interconnect layer 2M3) are illustrated, it will be appreciated by those skilled in the art that the invention is not limited in this regards as first interconnect structure 221 may also include four or more metal interconnect layers.

Preferably, the second epitaxial layer 320 includes a second interconnect structure 322. In this embodiment, the second interconnect structure 322 is implemented as a second cap metal layer. In alternative embodiments, the second interconnect structure 322 may further include several metal interconnect layers, or have a structure designed to meet practical requirements. Similarly, the second epitaxial layer 320 may further include a second protective layer 323, a second dielectric layer 321 and other like features. Second protective layer 323 may reside on a side of the second interconnect structure 322 opposite the second substrate 310 so as to protect the second interconnect structure 322, and the second interconnect structure 322 may be disposed within the second dielectric layer 321 for electrical insulation.

Preferably, as shown in FIG. 7, a first barrier layer 230 is formed on a side of the first substrate 210 opposite the first epitaxial layer 220 before step S23, so as to protect the first substrate 210 from being affected in a subsequent step S23. Materials from which the first barrier layer 230 can be fabricated to ensure an effective protection for the first substrate 210 include oxides such as silicon dioxide, nitrides such as silicon nitride, and carbides such as silicon carbonitride. Preferably, the first barrier layer 230 has a thickness of 10 Å to 1000 Å, for example, 50 Å, 100 Å, 300 Å, 500 Å, or 800 Å.

Referring to FIG. 8, in the third step S23, a first opening 281 is formed in the first substrate 210. The first opening 281 extends through the entire thickness of the first substrate 210 and has a side-to-bottom angle β of smaller than 90°. In other words, the first opening 281 is broader at the bottom and narrower at the top. Speaking in still another way, the first opening 281 has a cross section resembling a regular trapezoid in shape. The angle β may be set to various values in accordance with practical needs, such as, for example, 80°, 60°, 45°or 30°. A dry etching process may be employed to form the first opening 281, and a suitable recipe may be selected for the etching process according to the material of the first substrate 210. As the selection of a suitable etching recipe for a certain material is well-known to those of ordinary skill in the art, further description of it is omitted.

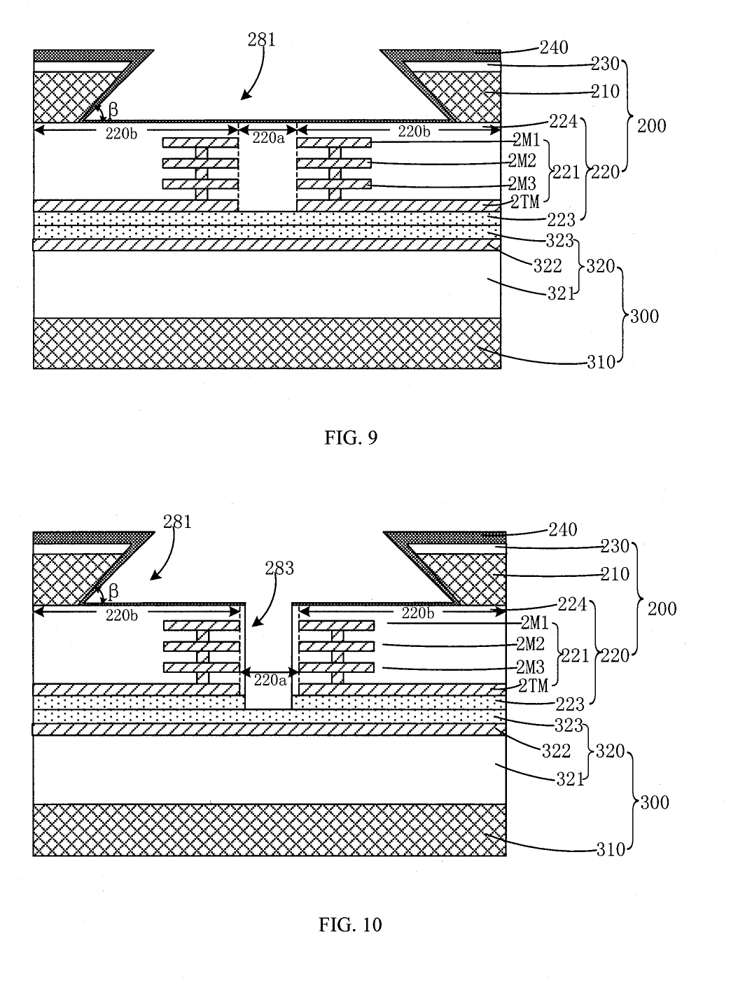

In this embodiment, a second barrier layer 240 is further formed over the side of the first substrate 210 opposite the first epitaxial layer 220 before a subsequent step S24 and after step S23. In this process, as shown in FIG. 9, the second barrier layer 240 covers an upper surface of the first barrier layer 230 or covers an upper surface of the first substrate 210 when the first barrier layer 230 is omitted. The second barrier layer 240 also covers both the inner side and the bottom of the first opening 281. As such, the second barrier layer 240 provides a protection layer for the first substrate 210 during the proceeding of the subsequent step S24. Similarly, materials from which the second barrier layer 240 can be fabricated to ensure an effective protection for the first substrate 210 include oxides such as silicon dioxide, nitrides such as silicon nitride, and carbides such as silicon carbonitride. Preferably, the second barrier layer 240 has a thickness of 10 Å to 5000 Å, for example, 50 Å, 100 Å, 300 Å, 1000 Å, or 3000 Å. Preferably, the second barrier layer 240 has a non-conformal step coverage, i.e., has inconsistent thicknesses inside and outside the first opening 281. Particularly, a thickness of the portion covering the outside of the first opening 281 (i.e., the upper surface of the first substrate 210 or the first barrier layer 230) is greater than a thickness of the portion covering the inside of the first opening 281 (i.e., the inner side and bottom of the first opening 281). In order for the non-conformal step coverage to occur, a CVD process or another suitable process can be selected to form the second barrier layer 240.

Considering there are further two openings, a third opening for exposing the second interconnect structure 322 and a second opening, to be subsequently formed in this embodiment, it is desirable to form these two openings by an all-in-one (AIO) etching process. Although the following description is made in the context of the second and third openings to be formed using an AIO etching process, it should be appreciated that the invention is not limited in this regards as the second and third openings can also be formed in separate processes.

Referring to FIG. 10, as described above, after the deposition of second barrier layer 240, a third opening 283 is formed within first opening 281. Since the third opening 283 is to be subsequently further subjected to an etching process, in this step, it is not necessarily formed to expose the underlying second interconnect structure 322 which is implemented as a second cap metal layer in this embodiment, as described above. In addition, in order to prevent possible detrimental effects on the first interconnect structure 221, the third opening 283 is desirably formed in the opening region 220a of the first epitaxial layer 220.

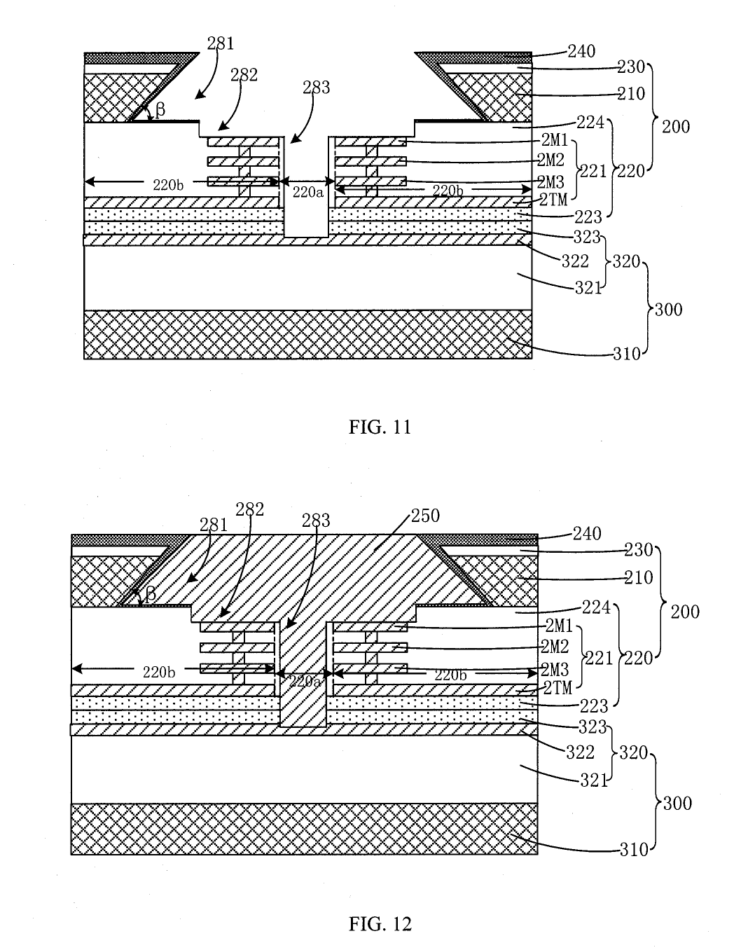

Afterward, in the fourth step S24, as shown in FIG. 11, the first epitaxial layer 220 is etched to form therein a second opening 282 to expose the first interconnect structure 221, using the first substrate 210 as a mask and the first opening 281 as a mask pattern. The formed second opening 282 has a size that is equal to a top-edge size of the first opening 281. Advantageously, using the first opening 281 as a mask pattern in forming the second opening 282 can eliminate the need for preparing a separate mask for the second opening 282, thus leading to process simplification, enhanced productivity and cost reduction.

In addition, the etching process of this step is an AIO etching process, wherein during the first epitaxial layer 220 is being etched to form the second opening 282, the third opening 283 is concurrently deepened and finally penetrates through the first epitaxial layer 220, exposing the second interconnect structure 322. For the sake of chip area saving, third opening 283 is preferably formed within the second opening 282.

Moreover, since the first interconnect structure 221 includes the first metal interconnect layer 2M1, the second metal interconnect layer 2M2, the third metal interconnect layer 2M3 and the first cap metal layer 2TM, the etching process may be stopped upon the first metal interconnect layer 2M1 being exposed in the second opening 282 (the one closest to first substrate 210 among the four layers of the interconnect structure 221). This is advantageous to preventing the second opening 282 from having an unnecessarily large depth to save materials, energy and time consumed in the etching process.

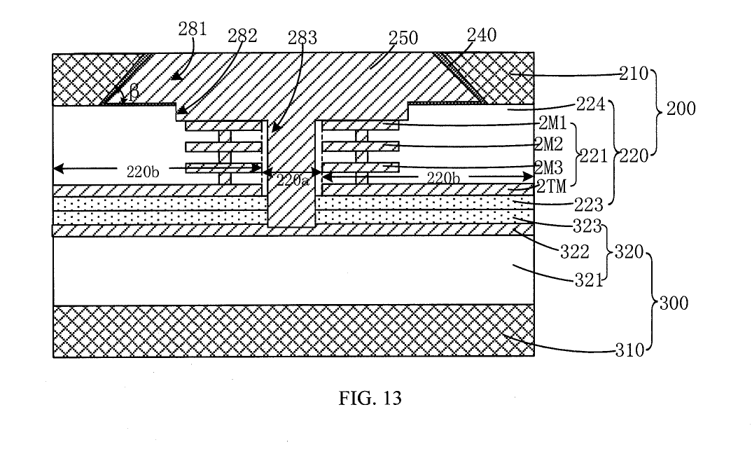

After step S24, a conductive layer 250 may be further formed, filling each of the first opening 28, the second opening 282 and the third opening 283, as shown in FIG. 12, and thus coming in contact with both first interconnect structure 221 and second interconnect structure 322 to electrically connect them. Additionally, a planarization process can be further performed on the first substrate 210 to remove an undesirable portion of the conductive layer 250, the second barrier layer 240 and the first barrier layer 230 to result in the stacked chip as shown in FIG. 13.

In this embodiment, the first and second chips 200, 300 are implemented as a device chip and a logic chip, respectively, such that the formed stacked chip functions as a stacked sensor. It shall be appreciated, however, that it is within the scope of the present invention for the first and second chips 200, 300 to be chips of other functions.

In conclusion, the methods of the present invention provide the following advantages over the prior art.

First, in the method of fabricating a semiconductor device of the invention, with the first opening having a side-to-bottom angle of smaller than 90° (i.e., broader at the bottom and narrower at the top) serving as a mask pattern for the subsequent etching step of forming the second opening in the substrate, the formed second opening gains a size equal to the top-edge size of the first opening. This circumvents the necessity of preparing a separate mask for forming the second opening, thus resulting in process simplification, enhanced productivity and cost reduction.

Secondly, by forming the first and second openings in the same manner as the foregoing fabricating method, the method of forming a stacked chip of the present invention can achieve all the same benefits, i.e., a simplified process, enhanced productivity and reduced cost.

Obviously, those skilled in the art may make various modifications and alterations without departing from the spirit and scope of the invention. It is therefore intended that the present invention be construed as including all such modifications and alterations insofar as they fall within the scope of the appended claims or equivalents thereof.

What is claimed is:

1. A method of fabricating a semiconductor device, comprising:
providing a substrate having a device function layer formed thereon;
forming a first opening in the device function layer, the first opening extending through the device function layer, the first opening having a side-to-bottom angle of smaller than 90°; and
etching the substrate to form therein a second opening by using the device function layer as a mask and the first opening as a mask pattern.

2. The method of claim 1, further comprising forming a first barrier layer on the device function layer, prior to forming the first opening in the device function layer.

3. The method of claim 2, wherein the first barrier layer is formed of an oxide, a nitride or a carbide.

4. The method of claim 2, wherein the first barrier layer has a thickness of 10 Å to 1000 Å.

5. The method of claim 1, further comprising forming a second barrier layer on the device function layer, after forming the first opening and prior to forming the second opening.

6. The method of claim 5, wherein the second barrier layer is formed of an oxide, a nitride or a carbide.

7. The method of claim 5, wherein the second barrier layer has a thickness of 10 Å to 5000 Å.

8. The method of claim 5, wherein the second barrier layer has a non-conformal step coverage region in the first opening.

9. A method of fabricating a stacked chip, comprising:
providing a first chip and a second chip, the first chip including a first substrate and a first epitaxial layer formed on the first substrate, the first epitaxial layer including a first interconnect structure, the second chip including a second substrate and a second epitaxial layer formed on the second substrate;
stacking the first and second chips with a side of the first epitaxial layer opposite the first substrate brought in contact with a side of the second epitaxial layer opposite the second substrate;
forming a first opening in the first substrate, the first opening extending through the first substrate, the first opening having a side-to-bottom angle of smaller than 90°; and
etching the first epitaxial layer to form therein a second opening by using the first substrate as a mask and the first opening as a mask pattern, the second opening exposing the first interconnect structure.

10. The method of claim 9, wherein the first interconnect structure includes a first cap metal layer and at least one metal interconnect layer, the first cap metal layer stacked with the at least one metal interconnect layer, the first cap metal layer located on a side of the at least one metal interconnect layer opposite the first substrate, and wherein the second opening exposes one of the at least one metal interconnect layer closest to the first substrate.

11. The method of claim 9, wherein the second epitaxial layer includes a second interconnect structure, and wherein the method further comprises forming a third opening within the first opening, the third opening exposing the second interconnect structure.

12. The method of claim 11, wherein the third opening is within the second opening.

13. The method of claim 12, wherein the second and third openings are formed by an all-in-one etching process.

14. The method of claim 11, wherein the first epitaxial layer includes an interconnect region and an opening region, wherein the first interconnect structure is disposed in the interconnect region, and the third opening is disposed in the opening region.

15. The method of claim 11, wherein the second interconnect structure includes a second cap metal layer, and wherein the third opening exposes the second cap metal layer.

16. The method of claim 9, further comprising filling the first and second openings with a conductive layer.

17. The method of claim 9, further comprising forming a first barrier layer on a side of the first substrate opposite the first epitaxial layer, prior to forming the first opening.

18. The method of claim 17, wherein the first barrier layer is formed of an oxide, a nitride or a carbide.

19. The method of claim 17, wherein the first barrier layer has a thickness of 10 Å to 1000 Å.

20. The method of claim 9, further comprising forming a second barrier layer on the side of the first substrate opposite the first epitaxial layer, after forming the first opening and prior to forming the second opening.

21. The method of claim 20, wherein the second barrier layer is formed of an oxide, a nitride or a carbide.

22. The method of claim 20, wherein the second barrier layer has a thickness of 10 Å to 5000 Å.

23. The method of claim 20, wherein the second barrier layer has a non-conformal step coverage region in the first opening.
